(19) United States
(12) Patent Application Publication
(10) Pub. No.: US 2012/0049358 A1
(43) Pub. Date: Mar. 1, 2012

(54) Semiconductor Device and Semiconductor Process for Making the Same

(76) Inventor: Bin-Hong Cheng, Kaohsiung (TW)

(21) Appl. No.: 12/862,428

(22) Filed: Aug. 24, 2010

(51) Int. Cl. H01L 23/48; H01L 21/768; H01L 23/488; H01L 21/60

(52) U.S. Cl. 257/738; 438/613; 438/666; 257/774; 257/E21.576; 257/E21.506; 257/E23.023; 257/E23.011

(57) ABSTRACT

The present invention relates to a semiconductor device and a semiconductor process for making the same. The semiconductor device of the present invention includes a semiconductor substrate, at least one conductive via and at least one insulation ring. The semiconductor substrate has a first surface. The conductive via is disposed in the semiconductor substrate. Each conductive via has a conductor and an insulation wall disposed the peripheral of the conductor, and the conductive via is exposed on the first surface of the semiconductor substrate. The insulation ring is disposed the peripheral of the conductive via, and the depth of the insulation ring is smaller than that of the insulation wall. Since the insulation ring is disposed the peripheral of the conductive via, the insulation ring can protect the end of the conductive via from being damaged. Furthermore, the size of the insulation ring and the conductive via is larger than the conventional conductive via, the semiconductor device of the invention can utilize surface finish layer, RDL or UBM to easily connect the other semiconductor device.

### BACKGROUND OF THE INVENTION

1. Field of the Invention

The present invention relates to a semiconductor device and a semiconductor process for making the same.

2. Description of the Related Art

FIG. 1 shows a cross-sectional view of a conventional silicon chip. The conventional silicon chip 30 has a silicon substrate 31, at least one electrical device 32, at least one through via 33, a passivation layer 34 and a redistribution layer 35. The silicon substrate 31 has a first surface 311, a second surface 312 and at least one through hole 313. The electrical device 32 is disposed in the silicon substrate 31, and exposed to the second surface 312 of the silicon substrate 31. The through via 33 penetrates the silicon substrate 31. The through via 33 comprises a barrier layer 333 and a conductor 334. The barrier layer 333 is disposed on the side wall of the through hole 313, and the conductor 334 is disposed in the barrier layer 333. The through via 33 has a first end 331 and a second end 332. The first end 331 is exposed to the first surface 311 of the silicon substrate 31, and the second end 332 connects the electrical device 32. The passivation layer 34 is disposed on the first surface 311 of the silicon substrate 31, and the passivation layer 34 has a surface 341 and at least one opening 342. The opening 342 exposes the first end 331 of the through via 33. The redistribution layer 35 is disposed on the surface 341 and the opening 342 of the passivation layer 34, and the redistribution layer 35 has at least one electrically connecting area 351, and the electrically connecting area 351 connects the first end 331 of the through via 33.

The conventional silicon chip 30 has the following disadvantages. The diameter of the opening 342 of the passivation layer 34 must be smaller than the diameter of the through hole 313 of the silicon substrate 31, otherwise the electrically connecting area 351 of the redistribution layer 35 will directly contact the silicon substrate 31, which will lead to a short circuit. However, the passivation layer 34 is generally patterned by an exposing and developing process, and the resolution of the process is low, so accurate and precise patterns cannot be manufactured. Therefore, the diameter of the opening 342 of the passivation layer 34 is likely to be greater than the diameter of the through hole 313 of the silicon substrate 31, and the electrically connecting area 351 of the redistribution layer 35 will directly contact the silicon substrate 31, which will lead to a short circuit. On the other hand, if the passivation layer 34 is patterned by a high resolution process, more subsequent processes are needed, so the method will become complex and costly.

FIG. 2 shows a cross-sectional view of a conventional semiconductor element. The conventional semiconductor element 41 comprises a base material 418, a passivation layer 414, at least one electrical device 415, at least one through via structure 416 and a redistribution layer 417. The base material 418 has a first surface 411, a second surface 412 and at least one groove 413. The groove 413 opens at the first surface 411. The passivation layer 414 is located on the first surface 411.

The electrical device 415 is disposed in the base material 418 and exposed on the second surface 412 of the base material 418. The through via structure 416 is disposed in the groove 413 and protrudes from the first surface 411. The redistribution layer 417 is disposed on the passivation layer 414 and electrically connected to the through via structure 416.

FIG. 3 shows a cross-sectional view of a conventional package having the conventional semiconductor element. The package 40 comprises a substrate 44, a semiconductor element 41, a chip 43 and a protective material 45. The chip 43 is disposed on the semiconductor element 41, and is electrically connected to the redistribution layer 417 by the bumps 42. The protective material 45 is disposed on the substrate 44 and encapsulates the semiconductor element 41 and the chip 43.

The conventional package 40 has following defects. The passivation layer 414 is necessary; otherwise, the bumps 42 may electrically connect the semiconductor element 41, which will lead to a short circuit.

Therefore, it is necessary to provide a semiconductor device and a semiconductor process for making the same to solve the above problems.

### SUMMARY OF THE INVENTION

The present invention is directed to a semiconductor process, comprising the following steps: (a) providing a semiconductor device having a semiconductor substrate and at least one conductive via, wherein the semiconductor substrate has a first surface, the conductive via is disposed in the semiconductor substrate, the conductive via comprises a conductor and an insulation wall disposed the peripheral of the conductor and is exposed on the first surface of the semiconductor substrate; (b) forming a cavity disposed the peripheral of the conductive via on the first surface of the semiconductor substrate, wherein the cavity does not penetrate the semiconductor substrate; and (c) forming an insulation ring disposed the peripheral of the conductive via by filling an insulation material into the cavity, the depth of the insulation ring being smaller than that of the insulation wall.

The present invention is also directed to a semiconductor device, comprising a semiconductor substrate, at least one conductive via and at least one insulation ring. The semiconductor substrate has a first surface. The conductive via is disposed in the semiconductor substrate. Each conductive via has a conductor and an insulation wall disposed the peripheral of the conductor, and the conductive via is exposed on the first surface of the semiconductor substrate. The insulation ring is disposed the peripheral of the conductive via, and the depth of the insulation ring is smaller than that of the insulation wall.

Since the insulation ring is disposed the peripheral of the conductive via, the insulation ring can protect the end of the conductive via from being damaged. Furthermore, the size of the insulation ring and the conductive via is larger than the conventional conductive via, the semiconductor device of the invention can utilize surface finish layer, RDL or UBM to easily connect the other semiconductor device.

### BRIEF DESCRIPTION OF THE DRAWINGS

FIG. 1 shows a cross-sectional view of a conventional silicon chip;

FIG. 2 shows a cross-sectional view of a conventional semiconductor element;

FIG. 3 shows a cross-sectional view of a conventional package having the conventional semiconductor element;

FIGS. 4 to 12 show the schematic views of the semiconductor process for making a semiconductor device according to a first embodiment of the present invention;

FIG. 13 shows the partially enlarged schematic view of the semiconductor device according to a second embodiment of the present invention;

FIG. 14 shows the partially enlarged schematic view of the semiconductor device according to a third embodiment of the present invention; and

FIGS. 15 to 22 show the schematic views of the semiconductor process for making a semiconductor package according to the third embodiment of the present invention.

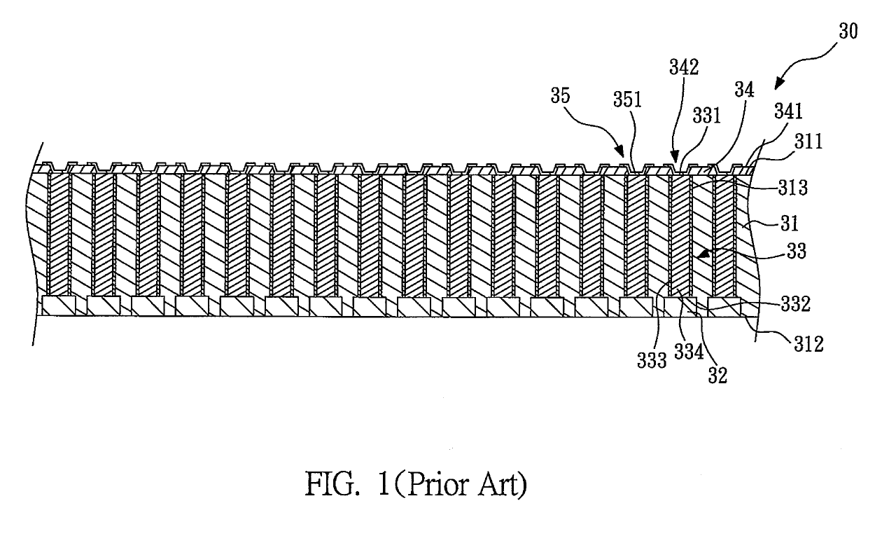

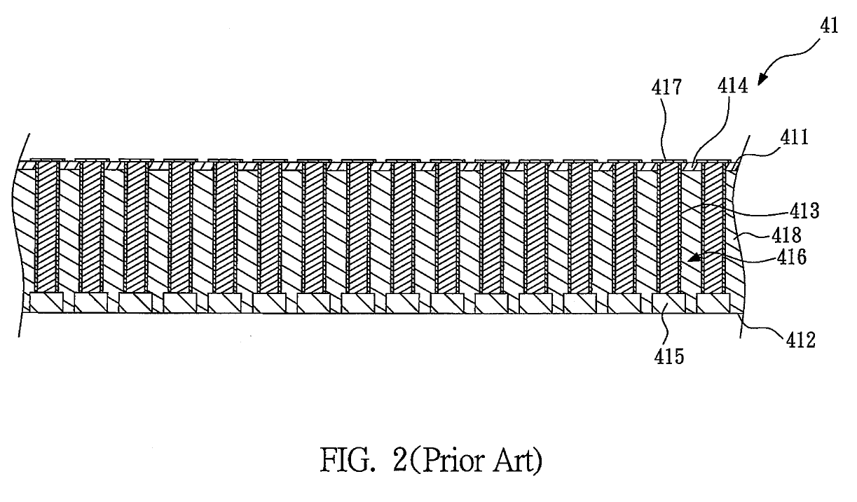

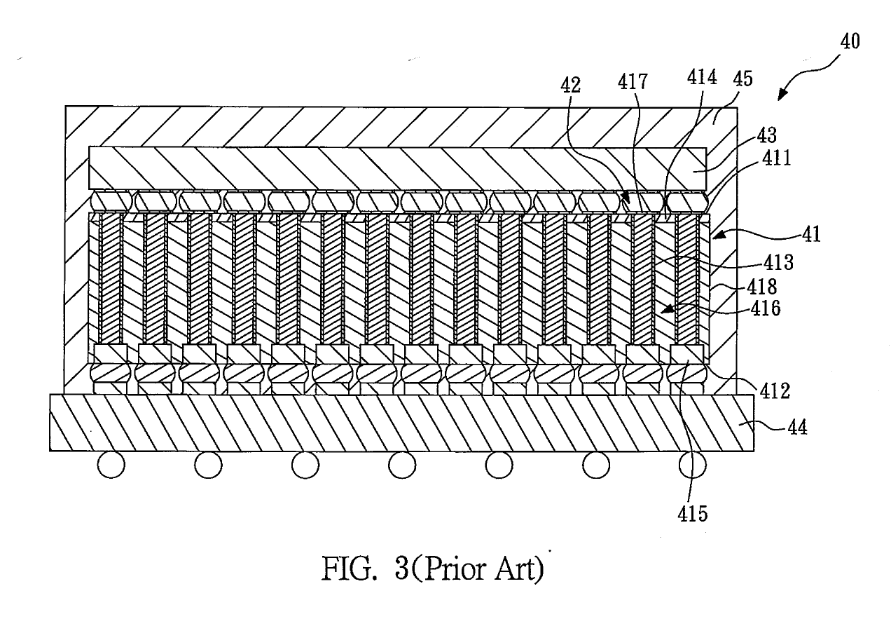

### DETAILED DESCRIPTION OF THE INVENTION

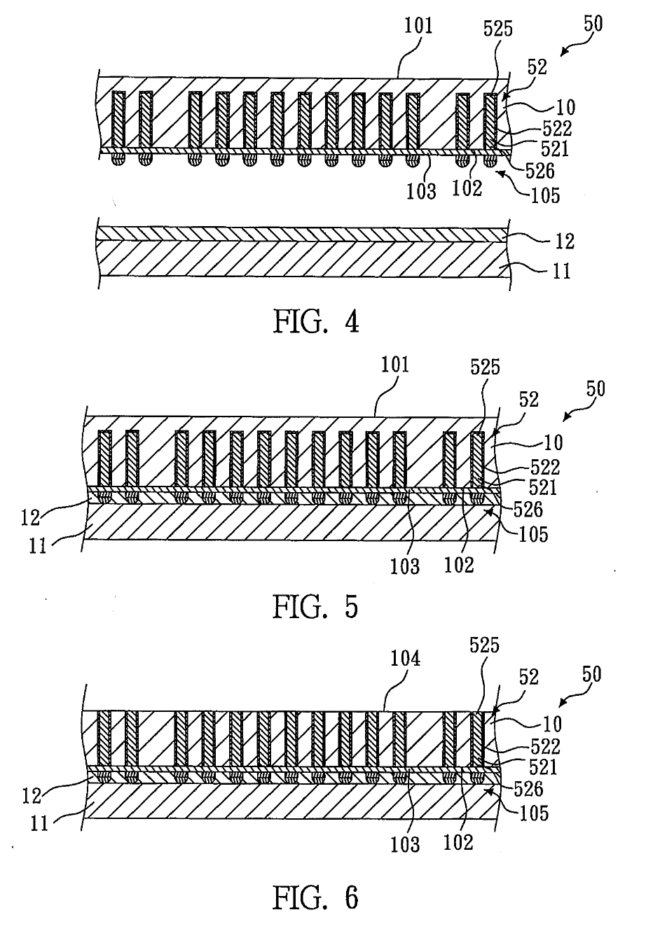

FIGS. 4 to 12 show the schematic views of the semiconductor process for making a semiconductor device according to the first embodiment of the present invention. Referring to FIG. 4, it shows a semiconductor device 50 and a first carrier 11. The semiconductor device 50 comprises a semiconductor substrate 10 and at least one conductive via 52. The semiconductor substrate 10 has an upper surface 101, a second surface 102, an active layer 103 and a plurality of conductive elements 105. In this embodiment, the semiconductor substrate 10 is a wafer. The active layer 103 is disposed on the second surface 102, and the conductive elements 105 are disposed adjacent to the active layer 103. The conductive via 52 is disposed in the semiconductor substrate 10.

The conductive via 52 has a conductor 521 and an insulation wall 522 disposed the peripheral of the conductor 521. The conductive via 52 further comprises a first end 525 and a second end 526. The second end 526 is connected to the active layer 103, and the conductive via 52 does not penetrate through the semiconductor substrate 10; that is, the first end 525 of the conductive via 52 does not be exposed on the upper surface 101 of the semiconductor substrate 10. In this embodiment, the conductor 521 of the conductive via 52 is made of copper.

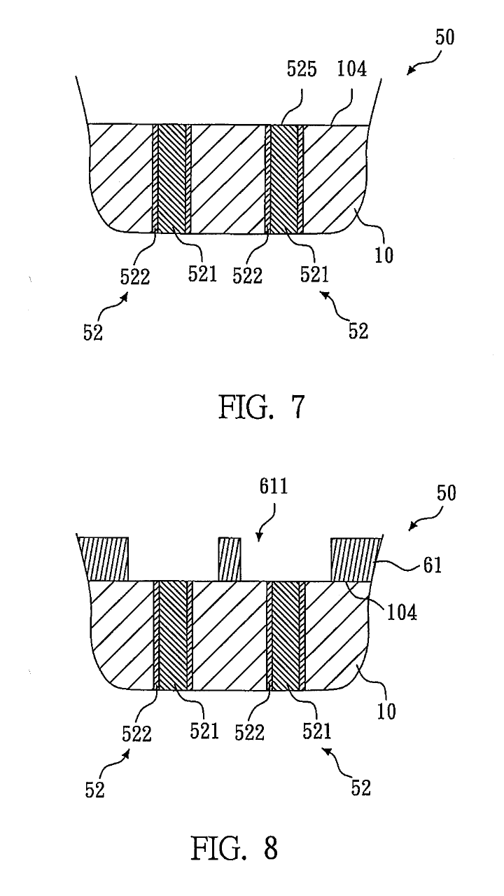

Referring to FIG. 5, the second surface 102 of the semiconductor substrate 10 is mounted to the first carrier 11 by a first adhesive layer 12. As shown in FIG. 6, part of the semiconductor substrate 10 is removed by grinding the upper surface 101, wherein a first surface 104 is formed and the conductive via 52 are exposed on the first surface 104. Preferably, the first end 525 of the conductive via 52 is exposed on the first surface 104 of the semiconductor substrate 10, referring to FIG. 7 showing a partially enlarged schematic view of the semiconductor device 50.

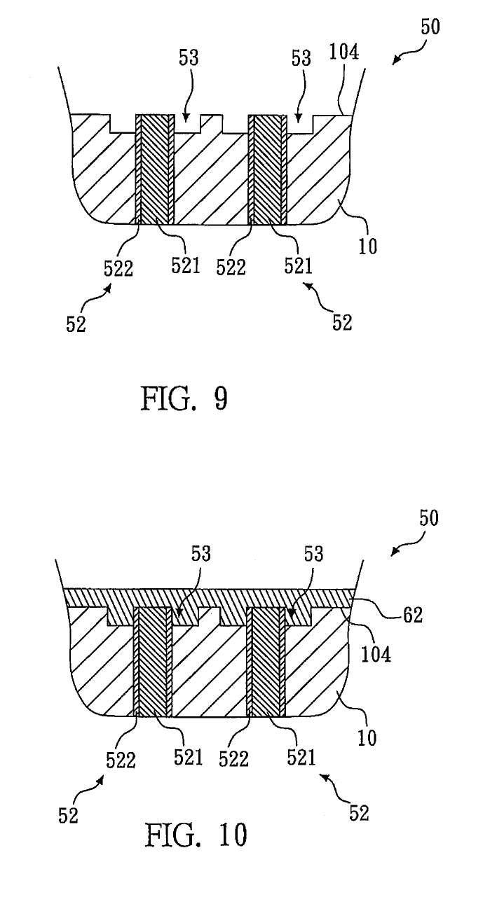

Referring to FIGS. 8 and 9, they show the partially enlarged schematic views for forming a cavity disposed the peripheral of the conductive via. The cavity 53 (as shown in FIG. 9) is formed and disposed the peripheral of the conductive via 52 on the first surface 104 of the semiconductor substrate 101. The cavity 53 (as shown in FIG. 9) does not penetrate the semiconductor substrate 10.

In this embodiment, the cavity 53 is formed by the following steps. A photo-resist layer 61 (as shown in FIG. 8) is formed on the first surface 104 of the semiconductor substrate 10. A first opening 611 is formed in the photo-resist layer 61, the position of the first opening 611 is corresponding to the cavity 53 and the conductive via 52. An area of a cross section of the first opening 611 is larger than that of the conductive via 52. Then, part of the first surface 104 of the semiconductor substrate 10 is etched to form the cavity 53 according to the first opening 611. The photo-resist layer 61 is removed.

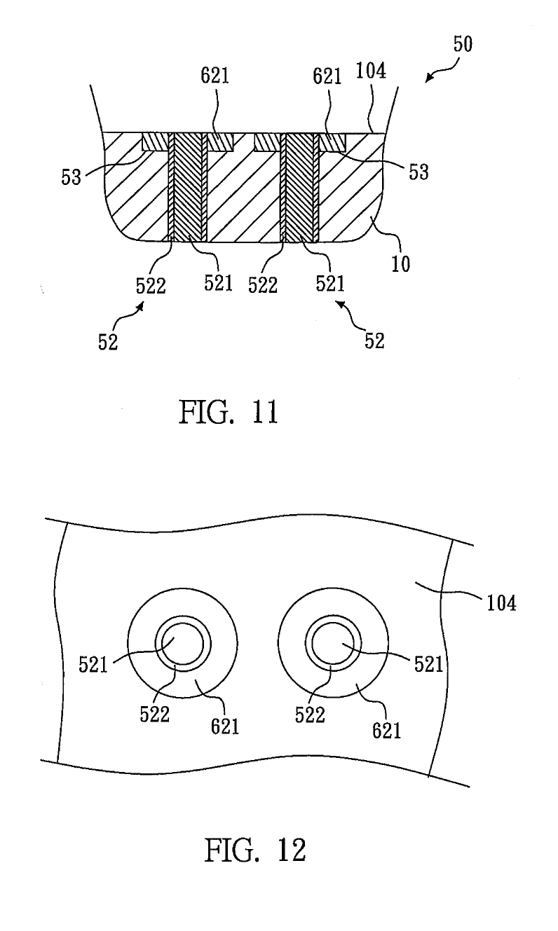

Referring to FIGS. 10 and 11, they show the partially enlarged schematic views for forming an insulation ring 621 disposed the peripheral of the conductive via. The insulation ring 621 is formed by filling an insulation material 62 into the cavity 53. The insulation ring 621 is disposed the peripheral of the conductive via 52, and the depth of the insulation ring 621 is smaller than that of the insulation wall 522.

In this embodiment, the insulation ring 621 is formed by the following steps. The insulation material 62 is formed on the first surface 104 of the semiconductor substrate 10 and is filled into the cavity 53. Then, part of the insulation material 62 is removed to expose the conductive via 52 and the insulation ring 621. Part of the insulation material 62 is removed by grinding or Chemical Mechanical Polishing (CMP).

FIG. 12 shows a partially enlarged top view of the semiconductor device 50. Referring to FIGS. 11 and 12, in this embodiment, the semiconductor device 50 comprises a semiconductor substrate 10, at least one conductive via 52 and at least one insulation ring 621. The semiconductor substrate 10 has a first surface 104. The conductive via 52 is disposed in the semiconductor substrate 10. Each conductive via 52 has a conductor 521 and an insulation wall 522 disposed the peripheral of the conductor 521, and the conductive via 52 is exposed on the first surface 104 of the semiconductor substrate 10. The insulation ring 621 is disposed the peripheral of the conductive via 52, and the depth of the insulation ring 621 is smaller than that of the insulation wall 522. The conductor 521 is formed as a circle shape, the insulation wall 522 is formed as a circular ring shape, and the insulation ring 621 is formed as a circular ring shape.

The semiconductor substrate 10 further comprises at least one cavity 53 disposed the peripheral of the conductive via 52, the cavity 53 does not penetrate the semiconductor substrate 10, and an insulation material is filled into the cavity 53 to form the insulation ring 621.

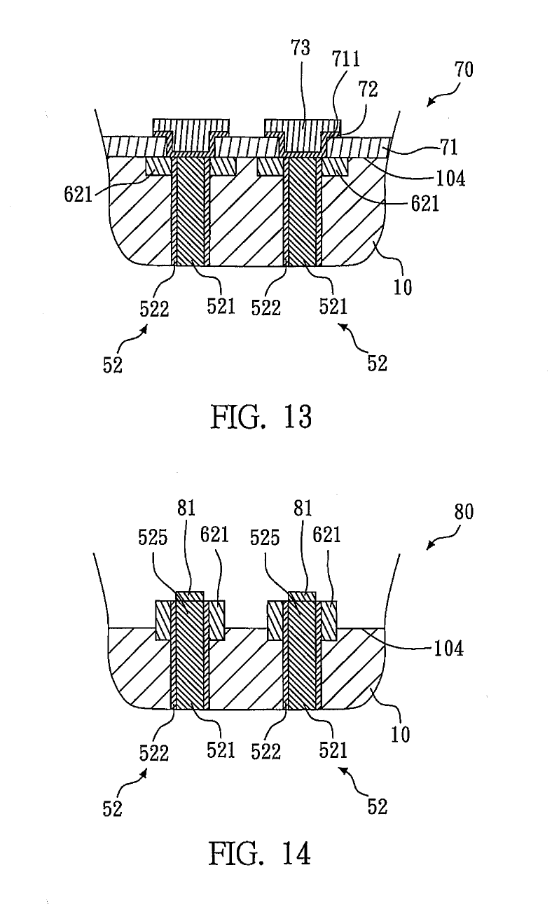

Referring to FIG. 13, it shows the partially enlarged schematic view of the semiconductor device having the insulation ring according to the second embodiment of the present invention. The semiconductor process for making the semiconductor device 70 of the second embodiment of the present invention can refer the above semiconductor process for making the semiconductor device 50 of the first embodiment of the present invention in FIGS. 4 to 11. After the semiconductor process of FIG. 11, a passivation layer 71 is formed on the first surface 104 of the semiconductor substrate 10. The passivation layer 71 has a second opening 711 to expose the conductive via 52 and part of the insulation ring 621. Then, a redistribution layer (RDL) 72 is formed on the conductive via 52 and part of the insulation ring 621 in the second opening 711 and on the part of the passivation layer 71. Then, an under ball metal (UBM) 73 is forming on the RDL 72.

Using the RDL 72 and the UBM 73, the electrical contacting position of the semiconductor device 70 can be flexibly adjusted to connect the other semiconductor device. Furthermore, since the insulation ring 621 is disposed the peripheral of the conductive via 52, the size of the RDL 72 can be larger than the conductive via 52. The semiconductor process of the second embodiment of the present invention is easily to implement and can ensure the electrical connection between the RDL 72 and the conductive via 52 when the conductive via 52 is tiny.

In addition, since the insulation ring 621 is disposed the peripheral of the conductive via 52, the diameter of the second opening 711 of the passivation layer 71 can be larger than the diameter of the conductive via 52, and the RDL 72 will not contact the semiconductor substrate 10. Therefore, the passivation layer 71 can be generally patterned by an exposing and developing process and by a low resolution process without accurate and precise patterns, so the method of the invention is simple and can save cost.

Referring to FIG. 14, it shows the partially enlarged schematic view of the semiconductor device having the insulation ring according to the third embodiment of the present invention. Part of the conductive via 52 and the insulation ring 621 protrude from the first surface 104.

The semiconductor device 80 of the third embodiment further comprises a surface finish layer 81 disposed on the first end 525 of the conductive via 52. The surface finish layer 81 can be used to connect the other semiconductor device (not shown), for example, the pad of the other semiconductor device. Since the insulation ring 621 is disposed the peripheral of the conductive via 52, the size of the surface finish layer 81 can be larger than the conductive via 52 and the passivation layer 414 as shown in FIG. 4 can be omitted. Furthermore, using the surface finish layer 81, the semiconductor device 80 of the third embodiment can easily connect the other semiconductor device (not shown).

In this embodiment, part of the conductive via 52 and the insulation ring 621 protrude from the first surface 104. Since the insulation ring 621 is disposed the peripheral of the conductive via 52, the insulation ring 621 can protect the first end 525 of the conductive via 52 from being damaged. Furthermore, the size of the insulation ring 621 together with the conductive via 52 is larger than the conventional conductive via, the semiconductor device 50 can easily connect to the other semiconductor device (not shown), for example, the pad of the other semiconductor device.

In other embodiment, thickness of the insulation ring 621 is not larger than 10 μm, outer diameter of the insulation ring 621 is not larger than 50 μm, and depth of the insulation ring is not larger than 30 μm.

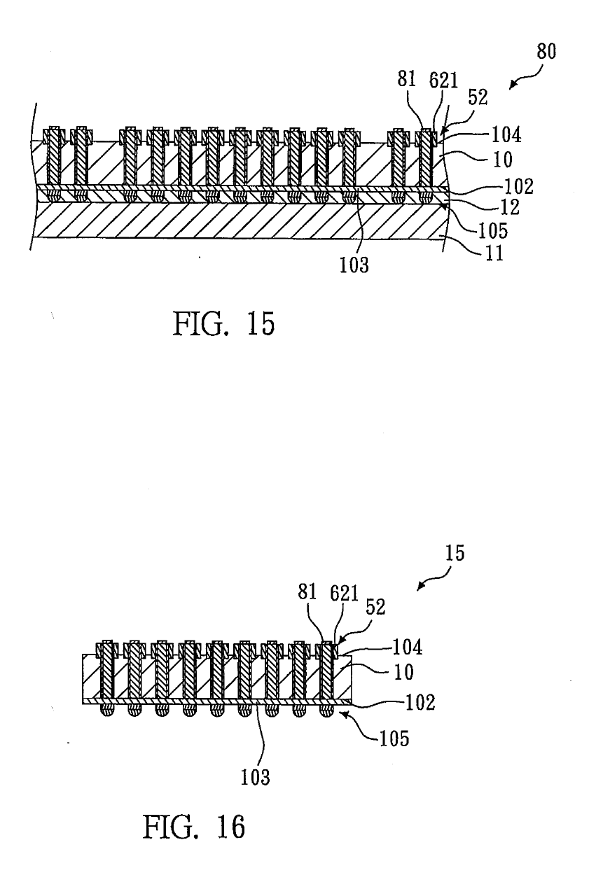

Referring to FIG. 15, it shows the schematic view of the semiconductor device having the insulation ring according to the third embodiment of the present invention. The semiconductor device 80 comprises the semiconductor substrate 10, at least one conductive via 52, the insulation ring 621 and the surface finish layer 81. The semiconductor substrate 10 has the first surface 104, the second surface 102, the active layer 103 and conductive elements 105.

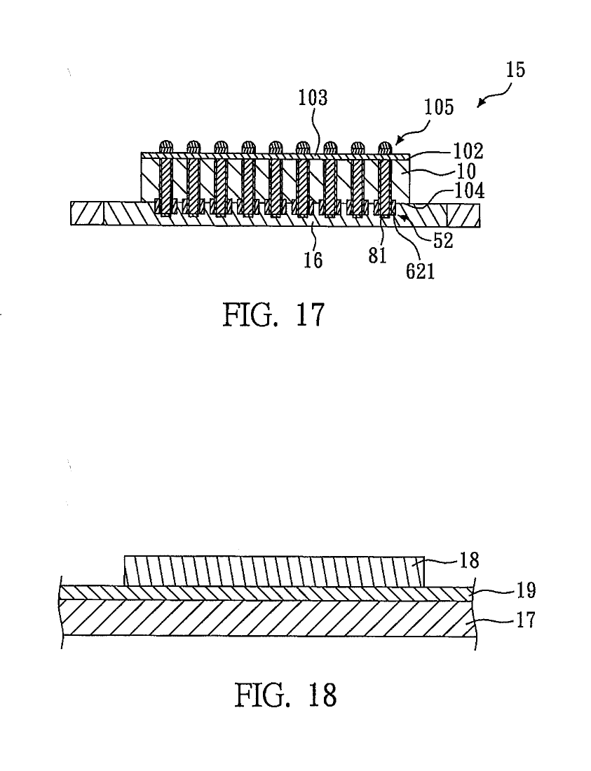

Referring to FIG. 16, the semiconductor device 80 is sawed and the first carrier 11 is removed, so as to form a plurality of semiconductor units 15. Referring to FIG. 17, the semiconductor unit 15 is mounted to a tape 16.

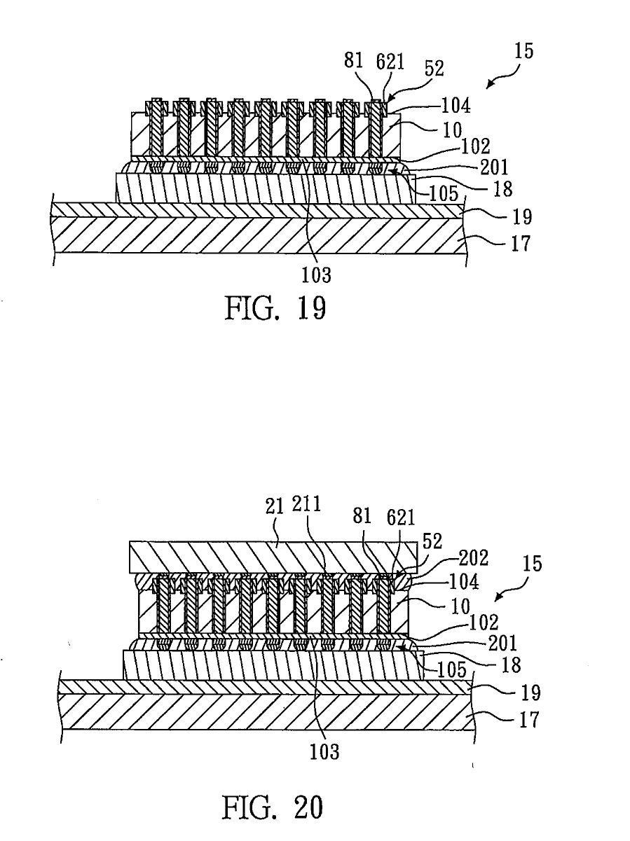

Referring to FIG. 18, it shows a second carrier 17 and a bottom substrate 18. The bottom substrate 18 is attached to the second carrier 17 by a second adhesive layer 19. Referring to FIG. 19, the semiconductor unit 15 is bonded to the bottom substrate 18. An underfill 201 is formed between the semiconductor unit 15 and the bottom substrate 18 so as to protect the conductive elements 105.

Referring to FIG. 20, a non-conductive polymer 202 is formed over the first surface 104, and a top semiconductor unit 21 is stacked on the semiconductor unit 15. Meanwhile, the surface finish layer 81 contacts a top conductive element 211 of the top semiconductor unit 21.

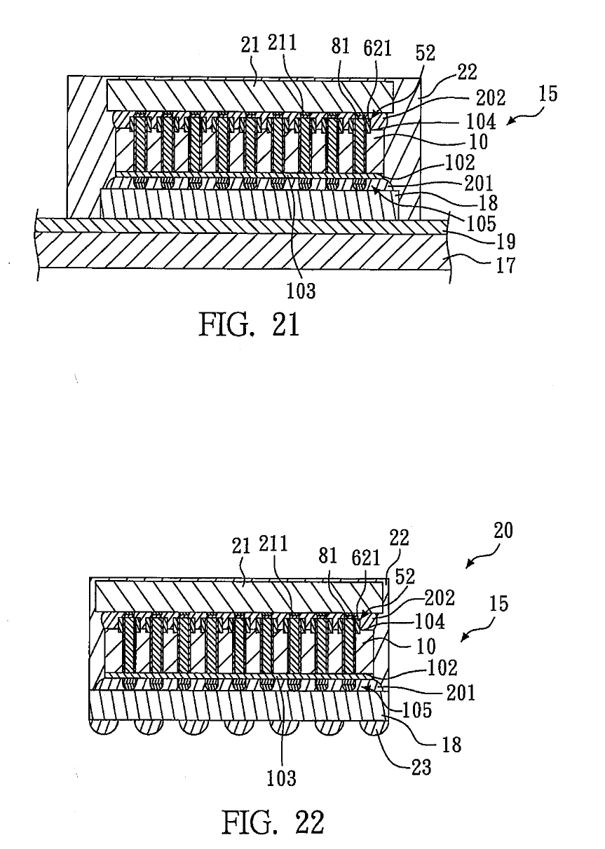

Referring to FIG. 21, a molding compound 22 is formed to encapsulate the bottom substrate 18, the semiconductor unit 15 and the top semiconductor unit 21. Referring to FIG. 22, the second carrier 17 and the second adhesive layer 19 are removed, and a plurality of solder balls 23 are formed on the bottom surface of the bottom substrate 18 to form a semiconductor package 20.

Since the insulation ring 621 is disposed the peripheral of the conductive via 52, the size of the surface finish layer 81 can be larger than the conductive via 52. Furthermore, using the surface finish layer 81 and the top conductive element 211, the semiconductor unit 15 can easily connect the top semiconductor unit 21.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A semiconductor process, comprising:
(a) providing a semiconductor device having a semiconductor substrate and at least one conductive via, wherein the semiconductor substrate has a first surface, the conductive via is disposed in the semiconductor substrate, the conductive via comprises a conductor and an insulation wall disposed the peripheral of the conductor and is exposed on the first surface of the semiconductor substrate;
(b) forming a cavity disposed the peripheral of the conductive via on the first surface of the semiconductor substrate, wherein the cavity does not penetrate the semiconductor substrate; and
(c) forming an insulation ring disposed the peripheral of the conductive via by filling an insulation material into the cavity, the depth of the insulation ring being smaller than that of the insulation wall.

2. The semiconductor process as claimed in claim 1, wherein the step (b) comprises:
(b1) forming a photo-resist layer on the first surface of the semiconductor substrate;
(b2) forming a first opening in the photo-resist layer, the position of the first opening corresponding to the cavity and the conductive via, wherein an area of a cross section of the first opening is larger than that of the conductive via;
(b3) etching part of the first surface of the semiconductor substrate to form the cavity according to the first opening; and
(b4) removing the photo-resist layer.

3. The semiconductor process as claimed in claim 1, wherein the step (c) comprises:
(c1) forming the insulation material on the first surface of the semiconductor substrate and into the cavity; and
(c2) removing part of the insulation material to expose the conductive via and the insulation ring.

4. The semiconductor process as claimed in claim 3, wherein part of the insulation material is removed by grinding or Chemical Mechanical Polishing (CMP).

5. The semiconductor process as claimed in claim 1, further comprising:
(d) forming a passivation layer on the first surface of the semiconductor substrate, the passivation layer having a second opening to expose the conductive via and part of the insulation ring;
(e) forming a redistribution layer (RDL) on the conductive via and part of the insulation ring in the second opening and on the part of the passivation layer; and
(f) forming an under ball metal (UBM) on the RDL.

6. The semiconductor process as claimed in claim 1, after step (c) further comprising a step of removing part of the first surface of the semiconductor substrate so that part of the conductive via and the insulation ring protrude from the first surface.

7. The semiconductor process as claimed in claim 6, wherein part of the first surface of the semiconductor substrate is removed by etching.

8. The semiconductor process as claimed in claim 1, after step (c) further comprising a step of forming a surface finish layer on the conductive via.

9. A semiconductor device, comprising:
a semiconductor substrate having a first surface;
at least one conductive via, disposed in the semiconductor substrate, each conductive via having a conductor and an insulation wall disposed the peripheral of the conductor, and the conductive via exposed on the first surface of the semiconductor substrate; and
at least one insulation ring, disposed the peripheral of the conductive via, the depth of the insulation ring being smaller than that of the insulation wall.

10. The semiconductor device as claimed in claim 9, wherein the semiconductor substrate further comprises at least one cavity disposed the peripheral of the conductive via, the cavity does not penetrate the semiconductor substrate, and an insulation material is filled into the cavity to form the insulation ring.

11. The semiconductor device as claimed in claim 9, further comprising:
a passivation layer disposed on the first surface of the semiconductor substrate, the passivation layer having a second opening to expose the conductive via and part of the insulation ring;
a redistribution layer (RDL) disposed on the conductive via and part of the insulation ring in the second opening and on the part of the passivation layer; and
an under ball metal (UBM) disposed on the RDL.

12. The semiconductor device as claimed in claim 9, wherein part of the conductive via and the insulation ring protrude from the first surface.

13. The semiconductor device as claimed in claim 9, wherein thickness of the insulation ring is not larger than 10 μm.

14. The semiconductor device as claimed in claim 9, wherein outer diameter of the insulation ring is not larger than 50 μm.

15. The semiconductor device as claimed in claim 9, wherein depth of the insulation ring is not larger than 30 μm.

16. The semiconductor device as claimed in claim 9, further comprising a surface finish layer disposed on the conductive via.
